(19) United States
(12) Patent Application Publication
(10) Pub. No.: US 2024/0275125 A1
(43) Pub. Date: Aug. 15, 2024

(54) OPTOELECTRONIC SEMICONDUCTOR CHIP AND COMPONENT

(71) Applicant: ams-OSRAM International GmbH, Regensburg (DE)

(72) Inventors: Hubert HALBRITTER, Dietfurt (DE); Sven GERHARD, Alteglofsheim (DE); Bruno JENTZSCH, Regensburg (DE); Tilman RÜGHEIMER, Regensburg (DE); Christoph WALTER, Regensburg (DE)

(73) Assignee: ams-OSRAM International GmbH, Regensburg (DE)

(21) Appl. No.: 18/563,049

(22) PCT Filed: May 24, 2022
(86) PCT No.: PCT/EP2022/064074

§ 371 Date: Nov. 21, 2023

(30) Foreign Application Priority Data
May 28, 2021 (DE) 10 2021 113 856.6

(51) Int. Cl. H01S 5/02255; H01S 5/02; H01S 5/02345; H01S 5/185; H01S 5/323; H01S 5/42

(52) U.S. Cl. CPC H01S 5/02255; H01S 5/0207; H01S 5/185; H01S 5/42; H01S 5/02345; H01S 5/32341

(57) ABSTRACT

The disclosed optoelectronic semiconductor chip includes a carrier, a semiconductor layer sequence on the carrier having at least one active zone for generating radiation, a layer of high optical refractive index on an output coupling facet of the semiconductor layer sequence for the output coupling of radiation, and a coating of low optical refractive index directly on an outer side of the layer of high optical refractive index for the total internal reflection of the radiation, wherein the semiconductor layer sequence is configured to guide the radiation in the active zone perpendicularly to a growth direction of the semiconductor layer sequence, and the layer of high optical refractive index is configured to deflect the radiation at the outer side parallel to the growth direction.

### CROSS-REFERENCE TO RELATED APPLICATIONS

The present application is a national stage entry from International Application No. PCT/EP2022/064074, filed on May 24, 2022, published as International Publication No. WO 2022/248487 A1 on Dec. 1, 2022, and claims priority to German Patent Application No. 10 2021 113 856.6, filed May 28, 2021, the disclosures of all of which are hereby incorporated by reference in their entireties.

### FIELD OF THE INVENTION

An optoelectronic semiconductor chip is provided.

Furthermore, a component having such an optoelectronic semiconductor chip is also provided.

### BACKGROUND OF THE INVENTION

In documents US 2009/0097519 A1 and WO 2019/170636 A1, semiconductor lasers with obliquely oriented deflection facets can be found.

A problem to be solved is to provide an optoelectronic semiconductor chip and a component that can be manufactured efficiently.

This object is solved, inter alia, by an optoelectronic semiconductor chip and by a component having the features of the independent patent claims. Preferred further embodiments are the subject of the dependent claims.

### SUMMARY OF THE INVENTION

According to at least one embodiment, the optoelectronic semiconductor chip comprises a carrier. The carrier may be the component mechanically carrying and supporting the semiconductor chip. It is possible that the carrier serves to electrically connect the semiconductor chip.

According to at least one embodiment, the optoelectronic semiconductor chip comprises a semiconductor layer sequence in which one or more active zones for generating radiation are located. The at least one active zone contains in particular at least one pn junction and/or at least one quantum well structure. The term quantum well does not unfold any meaning with respect to a dimensionality of the quantization. The term quantum well thus includes, for example, multi-dimensional quantum wells, one-dimensional quantum wires and quantum dots to be regarded as zero-dimensional as well as any combination of these structures.

The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or such as AlₙGaₘIn₁₋ₙ₋ₘAsₖP₁₋ₖ, where in each case 0≤n≤1, 0≤m≤1 and n+m≤1 as well as 0≤k<1. For example, 0<n≤0.8, 0.4≤m<1 and n+m≤0.95 as well as 0<k≤0.5 apply to at least one layer or to all layers of the semiconductor layer sequence.

In this context, the semiconductor layer sequence may comprise dopants as well as additional components. For the sake of simplicity, however, only the essential constituents of the crystal lattice of the semiconductor layer sequence, that is, Al, As, Ga, In, N or P, are mentioned, even if these may be partially replaced and/or supplemented by small amounts of additional substances.

Preferably, the semiconductor layer sequence is based on the material system AlₙIn₁₋ₙ₋ₘGaₘN or AlₙIn₁₋ₙ₋ₘGaₘAs. A radiation generated by the active zone in operation is in particular in the spectral range between 350 nm and 600 nm inclusive or between 590 nm and 960 nm inclusive.

According to at least one embodiment, the optoelectronic semiconductor chip comprises an optical high-refractive index layer. This at least one high-refractive index layer is located at at least one outcoupling facet of the semiconductor layer sequence. The at least one outcoupling facet serves for a radiation outcoupling of the radiation from the semiconductor layer sequence.

According to at least one embodiment, the optoelectronic semiconductor chip comprises an optical low-refractive index coating. The low-refractive index coating is preferably located directly on an outward side of the high-refractive index layer. The outward side faces away from the semiconductor layer sequence. In interaction with the high-refractive index layer, the low-refractive index coating serves for total reflection of the radiation.

According to at least one embodiment, the semiconductor layer sequence is configured to guide the radiation in the active zone perpendicular to a growth direction of the semiconductor layer sequence. For this purpose, the semiconductor layer sequence may comprise a waveguide and surrounding cladding layers, wherein the at least one active zone is located in the waveguide. The term parallel means, for example, that the radiation is guided with an angle of at most 150 or of at most 5° or of at most 2° to a normal plane to the growth direction.

According to at least one embodiment, the high-refractive index layer is configured to deflect the radiation on the outward side parallel to the growth direction. This applies, for example, with an angular tolerance of at most 45° or of at most 15° or of at most 5°.

In at least one embodiment, the optoelectronic semiconductor chip comprises a carrier, a semiconductor layer sequence on the carrier having at least one active zone for generating radiation, an optical high-refractive index layer on an outcoupling facet of the semiconductor layer sequence for outcoupling the radiation, and an optical low-refractive index coating directly on an outward side of the high-refractive index layer for total reflection of the radiation. The semiconductor layer sequence is configured to guide the radiation in the active zone perpendicular to a growth direction of the semiconductor layer sequence. The high-refractive index layer is configured to redirect the radiation at the outward side parallel to the growth direction, wherein the high-refractive index layer and the low-refractive index coating cooperate so that an interface between the high-refractive index layer and the low-refractive index coating is configured for total reflection of the radiation.

In particular, the semiconductor chip is a surface-emitting laser with a horizontal cavity, also referred to as HCSEL. ‘Surface emitting’ can mean that an emission side is oriented perpendicular to a growth direction of the semiconductor layer sequence, and ‘horizontal’ can mean in a direction parallel to the emission side. Thus, the semiconductor chip described herein preferably incorporates a deflection element, in particular formed from the combination of the high-refractive index layer and the low-refractive index coating, with the associated outcoupling facet forming, for example, a 45° deflection prism or oriented parallel to the growth direction. The semiconductor chip can thus be designed cost-effectively as a laser, since LED-like processes can be used in the fabrication and no specific laser processes, such as scribing and breaking, are required.

In addition to the significantly more cost-effective realization, wafer-level processing without the separation process, otherwise necessary for mirror coating with lasers, a number of applications can be served, for example, the pumping of wavelength conversion materials, for example, in projection applications. Other possible applications are in the aerospace sector as well as in the automotive sector or in the field of general lighting. In addition, the surface emission allows particularly flat packages and thus high synergies with LED package technology.

According to at least one embodiment, the optoelectronic semiconductor chip is a semiconductor laser. That is, in operation, the semiconductor chip is configured to emit a coherent radiation.

According to at least one embodiment, at a wavelength of maximum intensity of the radiation, the high-refractive index coating has a refractive index at least 0.6 or at least 0.8 or at least 1.0 higher than the low-refractive index coating. This applies in particular at room temperature, that is, 300 K, or at an intended operating temperature of the semiconductor chip.

According to at least one embodiment, a refractive index difference between the active zone and the high-refractive index layer is at most 0.3 or at most 0.2 or at most 0.1 or at most 0.05. This applies in particular at room temperature, that is, 300 K, or at an intended operating temperature of the semiconductor chip.

According to at least one embodiment, the high-refractive index layer is located directly at the outcoupling facet and the outcoupling facet is oriented transverse to the growth direction. For example, an angle between the growth direction and the outcoupling facet is then at least 15° or at least 30° and/or at most 75° or at most 60°, for example 45°.

According to at least one embodiment, the optoelectronic semiconductor chip further comprises one or more outcoupling mirrors directly on the outcoupling facet. The at least one outcoupling mirror is in particular a Bragg mirror.

According to at least one embodiment, the high-refractive index layer is located directly at the outcoupling mirror and the outcoupling facet is oriented parallel to the growth direction. Terms such as parallel or perpendicular apply here and in the following in particular with an angular tolerance of at most 15° or of at most 10° or of at most 5°.

According to at least one embodiment, the high-refractive index layer is a planarization layer for the outcoupling facet and/or for the outcoupling mirror. That is, the high-refractive index layer can reduce unevenness or a roughness of the outcoupling facet. In other words, the high-refractive index layer may be smoother and/or more planar on a side facing away from the outcoupling facet than the outcoupling facet itself. Regardless, the outcoupling facet, averaged over unevenness or a roughness, is preferably a flat surface.

According to at least one embodiment, the high-refractive index layer is an angle correction layer for the outcoupling facet, such that an angle between the outward side and the outcoupling facet is between 0.1° and 20° inclusive, or between 0.2° and 10° inclusive, or between 0.2° and 3° inclusive. That is, by means of the high-refractive index layer, an outcoupling direction of the radiation can be precisely set and/or adjusted compared to the outcoupling facet itself.

According to at least one embodiment, the optoelectronic semiconductor chip further comprises a metallization reflecting radiation directly at a side of the low-refractive index coating facing away from the outcoupling facet. Such a metallization allows a portion of the radiation generated in the semiconductor layer sequence that passes through the low-refractive index coating to still be utilized.

According to at least one embodiment, the carrier is a growth substrate of the semiconductor layer sequence. Thereby the radiation is emitted through the carrier.

According to at least one embodiment, the carrier is a substitute carrier to which the semiconductor layer sequence is attached by means of a fastening means. That is, it is possible that the growth substrate of the semiconductor layer sequence has been replaced by the substitute carrier or that the substitute carrier is provided in addition to the growth substrate. In this case, it is possible that radiation is emitted in the direction away from the carrier, in particular away from the substitute carrier, due to the outward side.

According to at least one embodiment, the carrier has a recess for the semiconductor layer sequence so that the carrier has a supporting surface facing the outcoupling facet. In this case, the low-refractive index coating can be applied to the supporting surface and the high-refractive index layer can be seated on the low-refractive index coating.

According to at least one embodiment, the semiconductor layer sequence, as seen in plan view and in at least one region without active zone, is attached to the low-refractive index coating deposited on the substrate by a fastening means. The fastening means may be based on at least one metal.

According to at least one embodiment, a further facet of the semiconductor layer sequence opposite the outcoupling facet is oriented obliquely to the growth direction. Alternatively, the further facet is oriented parallel to the growth direction.

According to at least one embodiment, a further supporting surface associated with the further facet is oriented parallel to the growth direction, so that the further supporting surface is configured to reflect radiation components of the radiation reaching the further supporting surface from the active zone back into the active zone.

According to at least one embodiment, the optoelectronic semiconductor chip further comprises optics for beam correction for the radiation. The optics, as seen in plan view, are located, for example, wholly or partially above the exterior surface. The optics may be larger than the exterior surface, as seen in plan view. It is possible that the optics are produced from the carrier.

In addition, a component having at least one optoelectronic semiconductor chip as described in connection with one or more of the above embodiments is disclosed. Features of the component are therefore also disclosed for the optoelectronic semiconductor chip, and vice versa.

In at least one embodiment, the component includes a plurality of the optoelectronic semiconductor chips and a mounting platform. The semiconductor chips are mounted on the mounting platform and, by means of the optics of the semiconductor chips, radiation directions of the semiconductor chips are matched to each other.

In the following, an optoelectronic semiconductor chip described herein and a component described herein are explained in more detail with reference to the drawing on the basis of exemplary embodiments. Identical reference signs indicate identical elements in the individual figures. However, no references to scale are shown, rather individual elements may be shown exaggeratedly large for better understanding.

### BRIEF DESCRIPTION OF THE DRAWINGS

### In the Figures

FIG. 1 shows a schematic cross-sectional view parallel to a resonator longitudinal direction of an exemplary embodiment of an optoelectronic semiconductor chip described herein,

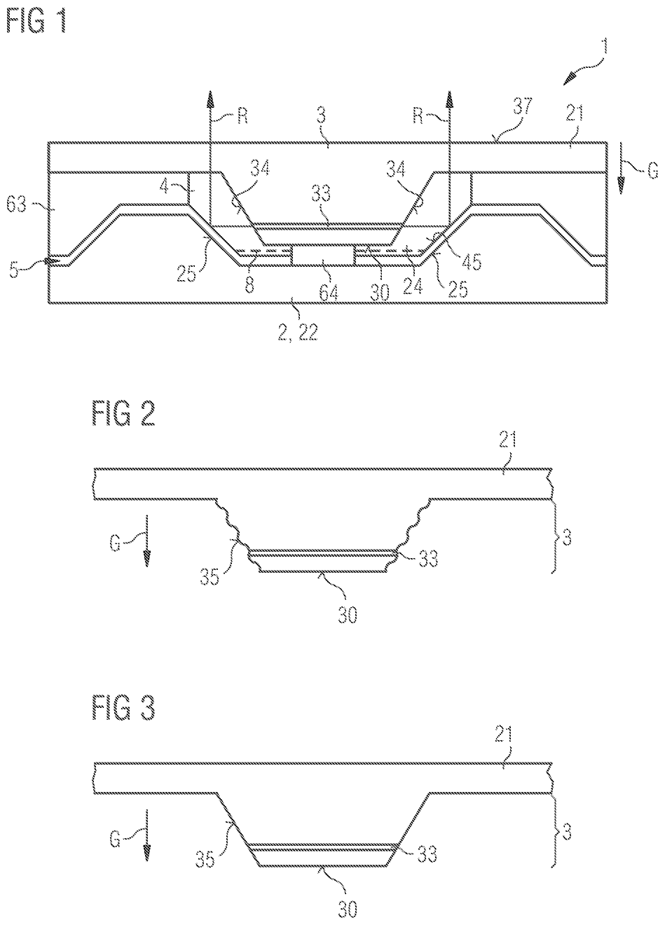

FIGS. 2 to 5 show schematic cross-sectional views of process steps for manufacturing the optoelectronic semiconductor chip of FIG. 1,

FIG. 6 shows a schematic cross-sectional view of an exemplary embodiment of an optoelectronic semiconductor chip described here,

FIGS. 7 and 8 show schematic top views of exemplary embodiments of optoelectronic semiconductor chips described herein,

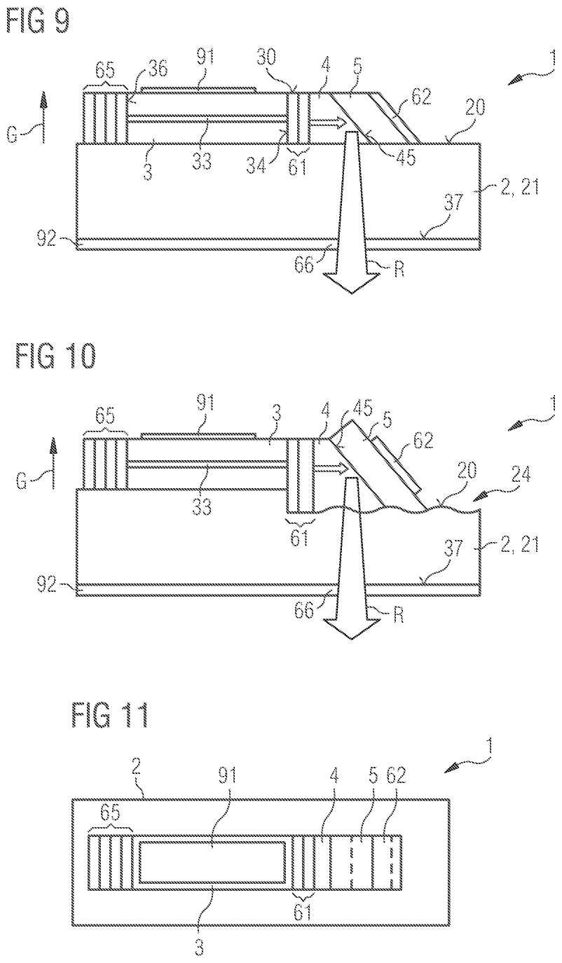

FIGS. 9 and 10 show schematic cross-sectional views of exemplary embodiments of optoelectronic semiconductor chips described herein,

FIG. 11 shows a schematic top view of an exemplary embodiment of an optoelectronic semiconductor chip described herein,

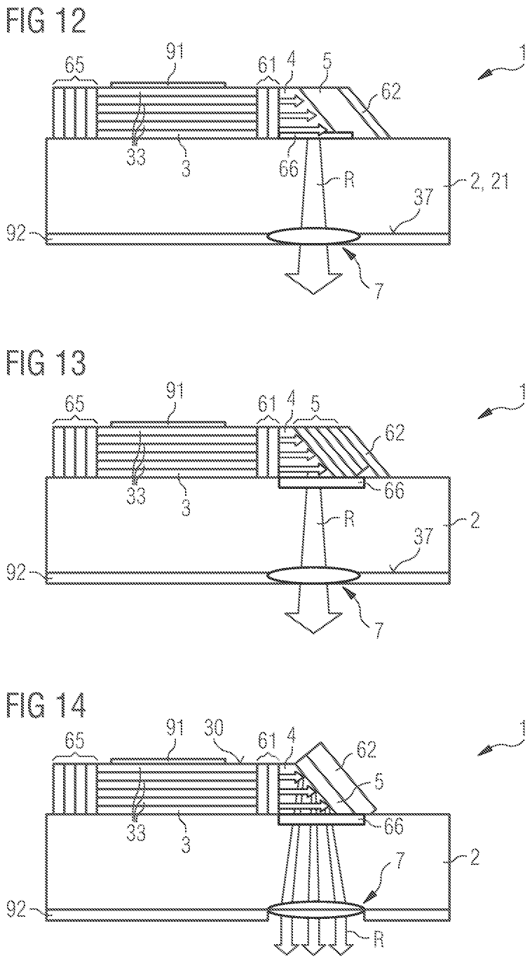

FIGS. 12 to 16 show schematic cross-sectional views of exemplary embodiments of optoelectronic semiconductor chips described herein,

FIGS. 17 to 28 show schematic cross-sectional views of process steps for manufacturing an exemplary embodiment of an optoelectronic semiconductor chip described herein,

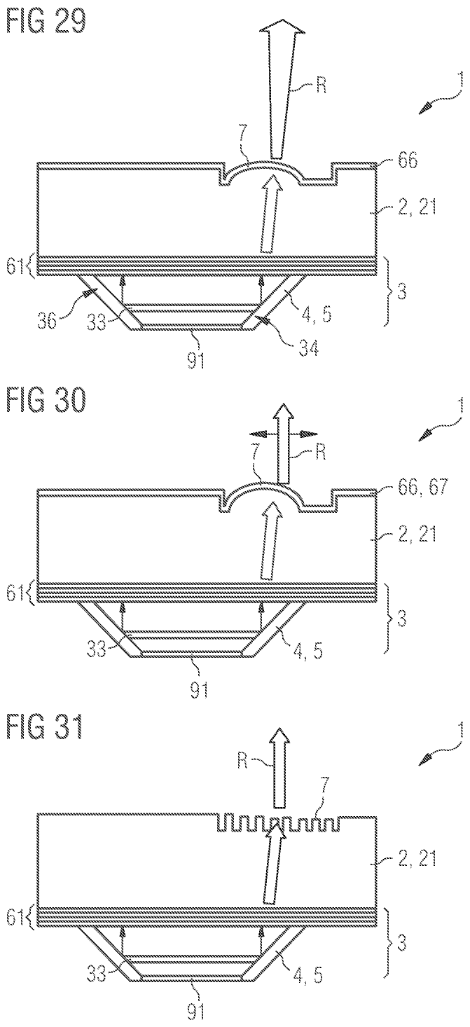

FIGS. 29 to 31 show schematic cross-sectional views of exemplary embodiments of optoelectronic semiconductor chips described herein, and

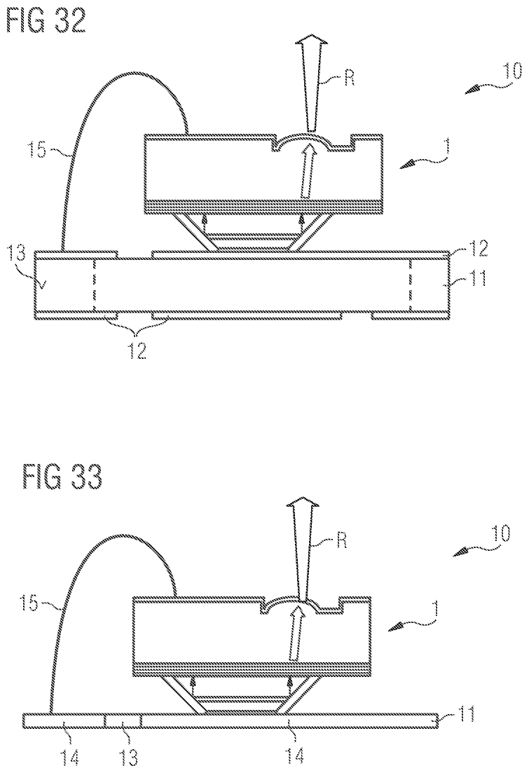

FIGS. 32 to 34 show schematic cross-sectional views of exemplary embodiments of components with optoelectronic semiconductor chips described herein.

### DETAILED DESCRIPTION

FIG. 1 shows an exemplary embodiment of an optoelectronic semiconductor chip 1. The semiconductor chip 1 is preferably a laser diode chip. The semiconductor chip 1 comprises a semiconductor layer sequence 3, which is, for example, made of AlInGaN. For example, an active zone 33 in the semiconductor layer sequence 3 is configured to generate blue light, green light and/or near-ultraviolet radiation R in operation. The active zone 33 may be embedded in a waveguide of the semiconductor layer sequence 3 and the waveguide may be limited by cladding layers of the semiconductor layer sequence 3, not explicitly drawn. The semiconductor layer sequence 3 may still be located on a growth substrate 21 as a carrier 2.

The semiconductor layer sequence 3 has two outcoupling facets 34 oriented approximately 45° to a growth direction G of the semiconductor layer sequence 3. Thereby, the semiconductor layer sequence 3 narrows in the direction away from the growth substrate 21. The radiation generated in the active zone 33 leaves the semiconductor layer sequence 3 through the outcoupling facets 34.

An optical high-refractive index layer 4 is located directly at each of the outcoupling facets 34. The high-refractive index layer 4 has the same or approximately the same refractive index as the semiconductor layer sequence 3. The high-refractive index layer 4 is, for example, made of NbO or LiNbO and can be applied by means of a sol-gel process, or is made of ZnS or also of sputtered, amorphous GaN. An outward side 45 of the high-refractive index layer 4 is comparatively smooth and may be oriented exactly at a 45° angle relative to the growth direction G. That is, by means of the high-refractive index layer 4, a correction of an orientation of the outcoupling facets 34 and a smoothing of the outcoupling facets 34 can be performed.

Directly on the outward side 45 is an optically low-refractive index coating 5. The low-refractive index coating 5 is preferably electrically insulating and is, for example, made of SiO₂ or of a fluoride, such as MgF or CaF. The low-refractive index coating 5 may be comparatively thin. In the interaction of the high-refractive index layer 4 and the low-refractive index coating 5, the outward side 45 is configured for total reflection of the radiation R.

A fastening means 63 is optionally located laterally next to the high-refractive index layer 4. The fastening means 63 is preferably electrically conductive and can be a solder. The fastening means 63 enables electrical contacting and mechanical connection of the semiconductor layer sequence 3 to a substitute carrier 22 as a further carrier 2. The substitute carrier 22 is preferably structured to match the high-refractive index layer 4 and is, for example, made of sapphire. Thus, the active zone 33 is located in or at a recess 24 of the further carrier 2, 22.

For further electrical contacting of the semiconductor layer sequence 3, the low-refractive index coating 5 can be perforated at a contact side 30 of the semiconductor layer sequence 3 facing the substitute carrier 22, so that an electrical contacting means 64 can pass through the low-refractive index coating 5 to the semiconductor layer sequence 3. At a supporting surface 25 of the substitute carrier 22, the low-refractive index coating 5 is optionally located directly on the substitute carrier 22.

In the direction away from the semiconductor layer sequence 3, the supporting surface 25 may be followed by a region oriented perpendicular to the growth direction G. The supporting surface 25 may be followed by another region oriented away from the growth substrate 21. This area can optionally be followed by a further area extending away from the growth substrate 21.

Furthermore, it is optionally possible for a gap 8 to be located on the contact side 30 between the low-refractive index coating 5 and the high-refractive index layer 4.

Thus, the radiation R generated in the active zone 33 passes through the outcoupling facets 34 into the high-refractive index layer 4 and to the respective outward side 45. At the outward side 45, the radiation R is directed to the growth substrate 21 by means of total reflection and is emitted, for example, from two regions on an emission side 37 of the growth substrate 21.

FIGS. 2 to 5 illustrate an exemplary manufacturing process for the optoelectronic semiconductor chip 1 shown in FIG. 1.

According to FIG. 2, the semiconductor layer sequence 3 is produced and patterned on the growth substrate 21 so that the active zone 33 remains only in an area between prefacets 35. The structuring of the semiconductor layer sequence 3 is carried out by means of dry etching, since it is difficult to generate the correct angle of the outcoupling facet 34 of, for example, 45° by means of wet etching. Due to the dry etching, however, the prefacets 35 are comparatively rough.

In the optional step shown in FIG. 3, the prefacets 35 are smoothed to form the outcoupling facets 34.

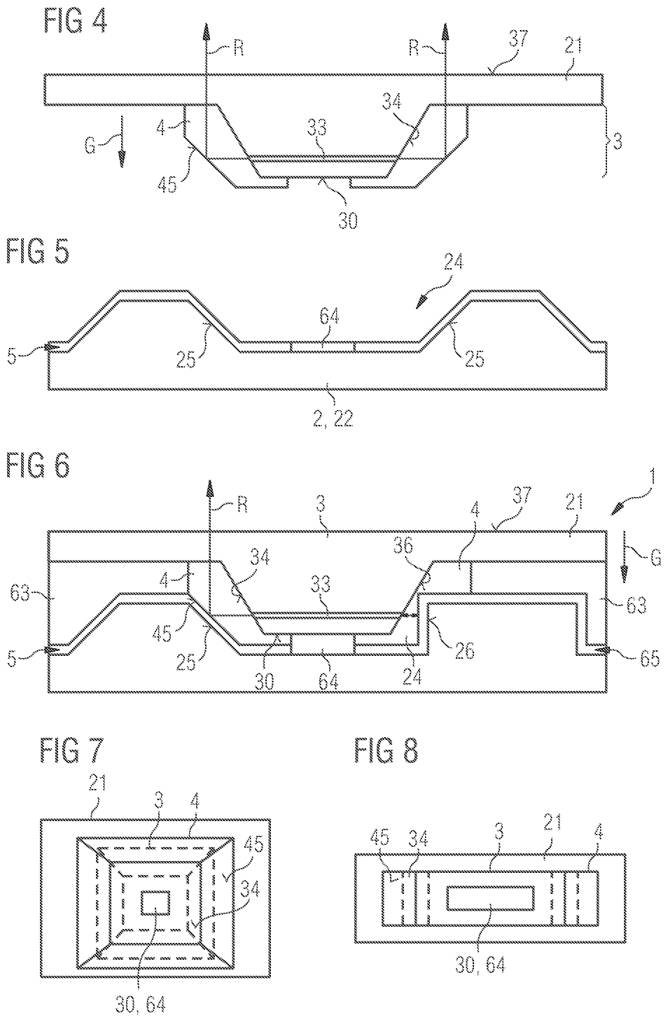

According to FIG. 4, the optically high-refractive index layer 4 is created and patterned. In this process, the outward sides 45 and an opening for the electrical contacting means are created. Thus, the high-refractive index layer 4 can be planar and oriented perpendicular to the growth direction G at the contact side 30, except for the opening. For example, the outward sides 45 are oriented at a 45° angle to the growth direction G. Close to the substrate 2, outside an area where the radiation R impinges on the outward sides 45, the high-refractive index layer 4 can optionally have flanks running parallel to the growth direction G.

A tolerance with which an angle of the outcoupling facets 34 of, for example, 45° to the growth direction G in FIGS. 2 and 3 can be generated is, for example, 0.5°. In contrast, due to the different material of the high-refractive index layer 4, the angle of the outward sides 45 can be produced, for example, with a tolerance of only 0.1° or of only 0.05°. An angle between the outward sides 45 and the associated outcoupling facets 34 is thus, for example, at least 0.1° and/or at most 3°.

In FIG. 5, it is illustrated that the further carrier 2, 22 is provided pre-structured and provided with the low-refractive index coating 5. Likewise, the low-refractive index coating 5 is already structured and optionally the electrical contacting means 64 is placed.

In a further process step, not drawn, the components of FIGS. 4 and 5 are assembled to arrive at the semiconductor chip 1 of FIG. 1.

The process of FIGS. 2 to 5 can thus be used to produce etched outcoupling facets 34 in combination with the high-refractive index layer 4 for perfect flanks to compensate for inaccuracies in the etch angle. Creating facets by means of scribing and breaking is thus not necessary to achieve the desired high accuracy in the flank angle, accompanied by a cost saving.

FIG. 6 illustrates another exemplary embodiment of the semiconductor chip 1. In this case, another facet 36 is present, which is opposite to the only one outcoupling facet 34. The further facet 36 is oriented parallel to the growth direction G. Also at the further facet 36, the high-refractive index layer 4 is directly present, but not the low-refractive index coating 5. Instead of the low-refractive index coating 5, an end mirror coating 65 is present, for example, a Bragg mirror. Accordingly, a further supporting surface 26 is associated with the further facet 36, which is oriented parallel to the growth direction G, as is the associated flank of the high-refractive index layer 4.

The end mirror coating 65 may start at the opening for the electrical contact means 64. Alternatively to the illustration in FIG. 6, it is also possible that the end mirror coating 65 does not replace the low-refractive index coating 5, but is additionally applied to a side of the low-refractive index coating 5 facing the semiconductor layer sequence 3.

In all other respects, the comments on FIGS. 1 to 5 apply in the same way to FIG. 6, and vice versa.

FIGS. 7 and 8 show top views of the semiconductor layer sequence 3, although the further carrier 2, 22 and the low-refractive index coating 5 are not drawn to simplify the illustration.

According to FIG. 7, the part of the semiconductor layer sequence 3 remaining after the generation of the outcoupling facets 45 is shaped as a truncated pyramid. This means that all lateral facets on this part of the semiconductor layer sequence 3 are oriented transversely to the growth direction G and have, for example, an angle to the growth direction G of approximately 45°.

In contrast, FIG. 8 illustrates that the facets not in contact with the radiation R can be oriented parallel or approximately parallel to the growth direction G.

In FIGS. 7 and 8, two of the outcoupling facets 34 are present in each case, as illustrated, for example, in connection with FIG. 1. In the same way, however, the structures of FIGS. 7 and 8 can also be applied to a semiconductor chip 1 with only one outcoupling facet 45 and, for example, with a further facet 36, compare FIG. 6.

In all other respects, the comments on FIGS. 1 to 6 apply in the same way to FIGS. 7 and 8, and vice versa.

The exemplary embodiments of FIGS. 9 and 10 relate in particular to GaN-based HCSELs with etched facets and low-power density on the emission side 37, for example, for emitting blue or green radiation R. In particular, with these semiconductor chips 1, as shown in FIGS. 9 and 10, it is possible to dispense with a hermetically gas-tight package or housing around the semiconductor chip 1.

Due to their high power density and narrow radiation emission pattern, GaN-based lasers usually require a hermetically sealed housing to protect an outcoupling facet. This is associated with considerable cost. By coupling out through the carrier 2 and by redirecting the radiation R into the carrier 2, the radiation R is widened in its path, in particular in the case of the semiconductor chips 1 according to FIGS. 9 and 10, in such a way that a power density on the emission side 37 drops to such an extent that hermetic encapsulation is no longer necessary.

The outcoupling facet 34 and/or the further facet 36 can be generated by etching as in the preceding embodiments. Furthermore, integrated on-chip TIR deflection mirrors are provided to realize a surface emitter according to the HCSEL concept; TIR stands for total internal reflection. Overall, this means a considerable cost reduction and performance advantages compared to other approaches and solutions, for example, by means of external deflection mirrors or the bonding of prisms or the like.

According to FIGS. 9 and 10, the AlInGaN-based semiconductor layer sequence 3 is deposited on the substrate 2, which is, for example, a growth substrate 21 made of GaN, with a refractive index of about 2.46. The outcoupling facet 34 and the opposite further facet 36 are oriented parallel to each other and to the growth direction G. The outcoupling facet 34 is preferably provided with a highly reflective Bragg mirror as an end mirror coating 65. At the further facet 36 there is preferably a highly reflective Bragg mirror as end mirror coating 65. The outcoupling facet 34 is preferably directly provided with an outcoupling mirror 61 having a lower reflectivity for the radiation R, for example, a reflectivity of at least 30% and/or of at most 80%. The outcoupling mirror 61 and/or the end mirror coating 65 can also serve as passivation of the facets 34, 36.

The optical high-refractive index layer 4 is located directly on a side of the outcoupling mirror 61 facing away from the semiconductor layer sequence 3 and is made, for example, of NbO with a refractive index of about 2.44 or of ZnS with a refractive index of about 2.47. The outward side 45 is oriented, for example, at a 45° angle with respect to the growth direction G.

Directly on the outward side 45 is the optically low-refractive index coating 5, which is, for example, made of SiOₓ, MgF or CaF and preferably has a refractive index of at most 2.0. The low-refractive index coating 5 preferably has a constant layer thickness across areas of the outward side 45 that come into contact with the radiation R.

Optionally, a reflective metallization 62, alternatively a Bragg mirror, is located directly on a side of the low-refractive index coating 5 facing away from the semiconductor layer sequence 3. The reflective metallization 62 is, for example, made of Al, Ag, Au or of a layer system Cr—Au, depending on the wavelength of the radiation R.

In order to sufficiently reduce the power density of the radiation R at the emission side 37, the carrier 2 preferably has a thickness of at least 200 μm and/or of at most 2 mm. For example, the thickness of the carrier 2 is 0.3 mm.

An effective thickness of the high-refractive index layer 4 in the plane of the active zone 33 and in the direction parallel to the active zone 33 is, for example, at least 2 μm or at least 8 μm and/or at most 0.2 mm or at most 0.1 mm or at most 30 μm. This means that the effective thickness of the high-refractive layer 4 can be significantly smaller than the thickness of the substrate 2.

For example, a thickness of the low-refractive index coating 5 is at least 0.2 μm and/or at most 2 μm.

The emission side 37 of the carrier 2 is optionally provided with an anti-reflective coating 66, for example, a λ/4 layer of SiOₓ or of SiOₓN_{y}, at least in a region relevant for the radiation R.

A first electrical contact layer 91 and a second electrical contact layer 92, which are metallic layers, for example, are preferably located on the carrier 2 on the emission side 37 as well as on the contact side 30 of the semiconductor layer sequence 3.

According to FIG. 9, a carrier top side 20 of the carrier 2, on which the semiconductor layer sequence 3 is located, is flat. However, the carrier top side 20 can also be structured, see FIG. 10, in order to be able to adjust the thickness of the carrier 2 according to the specific requirements. For example, the carrier 2 is thicker in the area of the semiconductor layer sequence 3 than in the area of the low-refractive index coating 5.

Due to the very good refractive index matching of NbO and GaN, no disturbing reflections occur at the corresponding interfaces during the NbO/GaN transition. In addition, NbO as a non-crystalline material can be etched well, for example, to produce the 45° outward side 45.

FIG. 11 illustrates a top view of the semiconductor chip 1 shown in FIG. 9. The semiconductor layer sequence 3 can thus be rectangular when viewed from above, and all facets can be oriented parallel to the growth direction G.

In all other respects, the comments on FIGS. 1 to 8 apply in the same way to FIGS. 9 to 11, and vice versa.

FIG. 12 shows an exemplary embodiment of the semiconductor chip 1, in which the semiconductor layer sequence 3 is based on the material system AlInGaAs and the active zone 33 is configured to generate red or near-infrared radiation R. As in all other embodiments, the semiconductor layer sequence 3 may comprise a plurality of the active zones 33. The active zones 33 may all be configured to generate radiation R of the same wavelength, or may be configured to generate radiation R of different wavelengths.

Also illustrated in FIG. 12 is that an optic 7 may be produced on or in the carrier 2. The optics 7 is, for example, a collimating lens. Such an optics 7 may also be present in all other embodiment examples. In particular, the semiconductor chip 1 of FIG. 1 is a GaAs-based HCSEL configured for pulsed operation with etched facets 34, 36.

Pulsed GaAs lasers, for example for LiDAR applications and especially triple-stack lasers with three active zones 33 and thus a thick, epitaxially grown semiconductor layer sequence 3, if realized as HCSEL, require an exact 450 slope across the whole semiconductor layer sequence 3, which is difficult to achieve due to the different materials in the active zones 33. If this is not ensured, high losses are incurred, especially for the deeper active zones 33 and the associated waveguides. In particular, it is difficult to precisely hit the 45° slope across the complete thickness of the semiconductor layer sequence 3 if the slope is still part of the resonator.

Also in the GaAs-based semiconductor chip 1 of FIG. 12, the facets 34, 36 are generated by etching and feature the integrated on-chip TIR deflection mirror, so that a HCSEL is realized. This means a significant cost reduction and performance advantages compared to other approaches and solutions, such as using external deflection mirrors, gluing prisms and the like. With this concept, efficiencies of the same order of magnitude as with standard edge emitter approaches can be achieved. This is especially true since the 45° outward side 45 is outside the actual resonator. Another advantage is that a deviation from the ideal 45° slope in the concept described here can be compensated for by compensating optics 7 on the emission side 37. This also applies to semiconductor chips 1 with only one active zone 33.

In the semiconductor chip 1 shown in FIG. 12, the carrier 2 is in particular a GaAs growth substrate 21 with a refractive index of about 3.6, which is transparent to wavelengths above about 870 nm. The optical high-refractive index layer 4 is again, for example, made of NbO with a refractive index of about 2.28 and is high-refractive compared to the low-refractive index coating 5 with a refractive index less than 2.0. The low-refractive index coating 5 is, for example, made of SiOₓ, MgF or CaF. The reflective metallization 62 is, for example, of Al, Ag, Au or Cr—Au.

In order to prevent a reflection of the radiation R at the interface between the carrier top side 20 and the high-refractive index layer 4, an anti-reflective coating 66 is preferably present between the carrier 2 and the high-refractive index layer 4. The anti-reflective coating 66 is, for example, a λ/4 layer of TiOₓ, in particular if the high-refractive index layer 4 is of SiOₓN_{y} or of NbO, where the SiOₓN_{y} may in particular have a refractive index of about 1.75. As an alternative to a single-layer antireflective coating 66, a multilayer system, such as a Bragg layer sequence, can also be used.

The optics 7 may also include fast axis compensation and/or be configured for angular correction with respect to the 90° deflection of the radiation R. The optics 7 is, for example, glued or bonded or etched into the carrier 2.

In all other respects, the comments on FIGS. 1 to 11 apply in the same way to FIG. 12, and vice versa.

FIG. 13 shows that the low-refractive index coating 5 can also be designed as a Bragg layer stack. This means that in this case the low-refractive index coating 5 does not need to act as a totally reflective coating in interaction with the high-refractive index coating 4. The same applies to all other embodiments.

In all other respects, the comments on FIG. 12 apply in the same way to FIG. 13, and vice versa.

FIG. 14 illustrates that the high-refractive index layer 4, the low-refractive index coating 5 and the optional reflective metallization 62 need not be planarized at the contact side 30. The same applies to all other embodiments.

Furthermore, it is shown in FIG. 14 that the optics 7 need not be a convex or biconvex converging lens, but may also be formed by a meta-optics or by a diffractive optical element or comprise a corresponding component. The same applies to all other embodiments.

In all other respects, the comments on FIGS. 12 and 13 apply in the same way to FIG. 14, and vice versa.

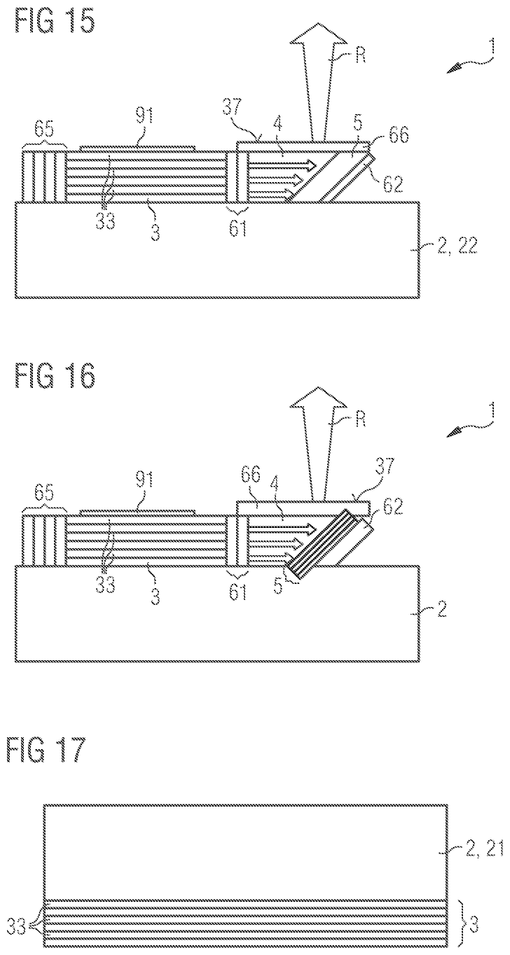

In the embodiment shown in FIG. 15, the growth substrate 21 has been replaced by the substitute substrate 22. Thus, the emission side 37 is located on a side of the high-refractive index layer 4 facing away from the substrate 2. The anti-reflective coating 66 may again be present.

In all other respects, the comments on FIGS. 12 to 14 apply in the same way to FIG. 15, and vice versa.

In FIG. 16 it is shown, based on FIG. 15, that the low-refractive index coating 5 can be designed as a Bragg mirror, analogous to FIG. 13. In all other respects, the comments on FIGS. 13 and 15 apply in the same way to FIG. 16, and vice versa.

FIGS. 17 to 28 show a fabrication method for a semiconductor chip 1 constructed as shown in FIG. 15, except for the form of the optional reflective metallization 62. For example, FIG. 17 shows that the semiconductor layer sequence 3 with the active regions 33 is grown continuously on the growth substrate 21.

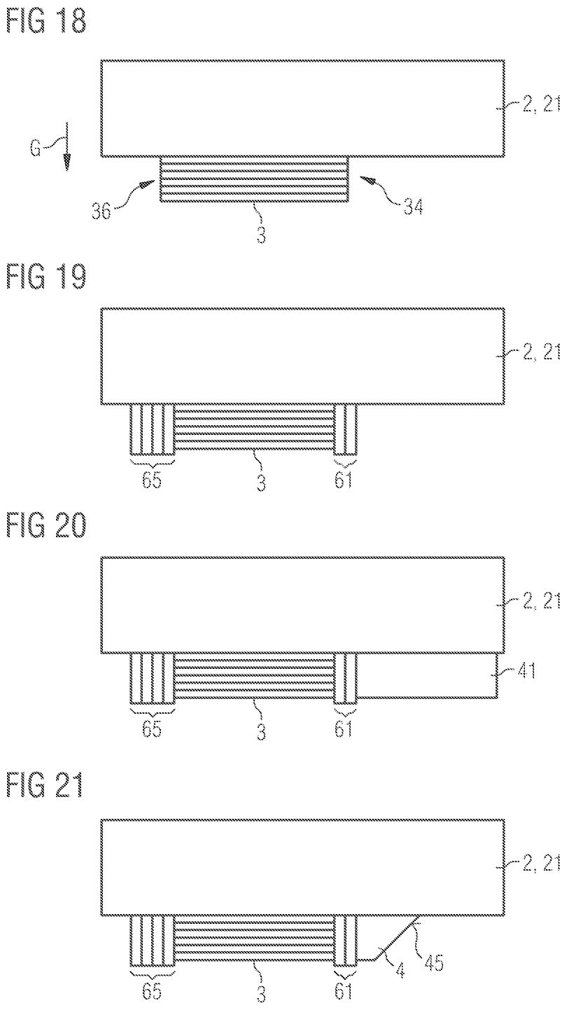

According to FIG. 18, the semiconductor layer sequence 3 is patterned so that the outcoupling facet 34 and the further facet 36 are formed. These facets 34, 36 are aligned parallel to the growth direction G. The facets 34, 36 are not produced by means of scribing and breaking, but by means of etching.

This etching may include or be a wet chemical and/or a dry chemical process.

In the step of FIG. 19, the end mirror coating 65 as well as the outcoupling mirror 61 are produced at the facets 34, 36. The end mirror coating 65 and the outcoupling mirror 61 are preferably Bragg mirrors.

In the step of FIG. 20, a starting layer 41 for the high-refractive index layer is deposited. The starting layer 41 can be deposited over a large area, optionally only on the outcoupling mirror 61.

FIG. 21 shows that the high-refractive index layer 4 is patterned by etching to form the outward side 45. Then, see FIG. 22, the low-refractive index coating 5 is produced, preferably with a constant layer thickness.

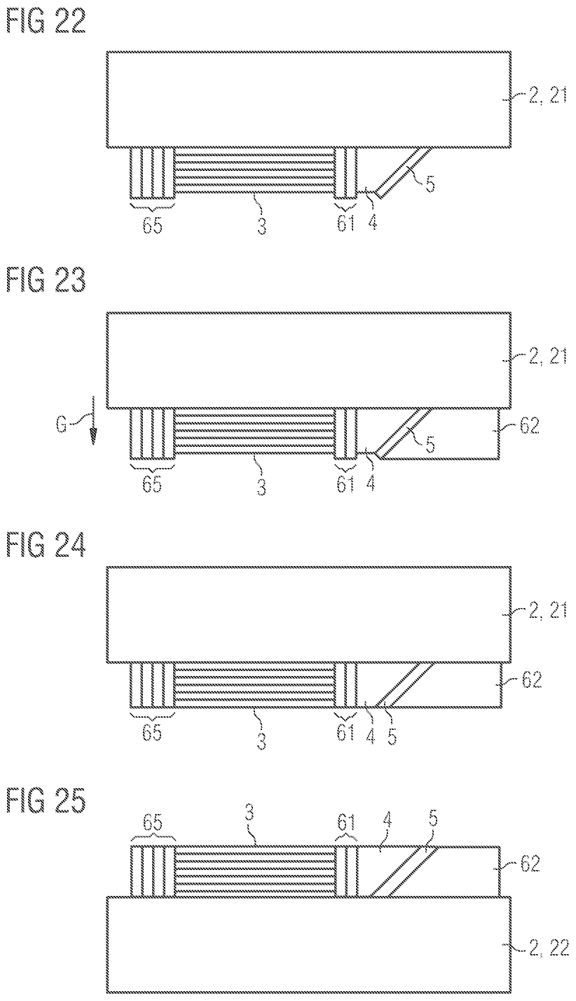

At least one metal for the optional reflective metallization 62 is then applied. Unlike shown in FIG. 15, this metal can also be applied over a large area and relatively thick. This metal can also be located on a side of the end mirror coating 65 facing away from the semiconductor layer sequence 3, unlike shown in FIG. 23. A thickness of the reflective metallization 62 in the direction parallel to the growth direction G may be greater than or equal to the thickness of the semiconductor layer sequence 3.

In the optional step of FIG. 24, the layers 4, 5, 62 are planarized so that the layers 4, 5, 62 can be flush with the semiconductor layer sequence 3 and with the mirrors 61, 65 in the direction away from the growth substrate 21.

According to FIG. 25, re-bonding has been performed so that the substitute carrier 22, which is made of Si or Ge, for example, is attached to a side of the semiconductor layer sequence 3 facing away from the growth substrate 21. After attaching the substitute carrier 22, the growth substrate 21 was removed.

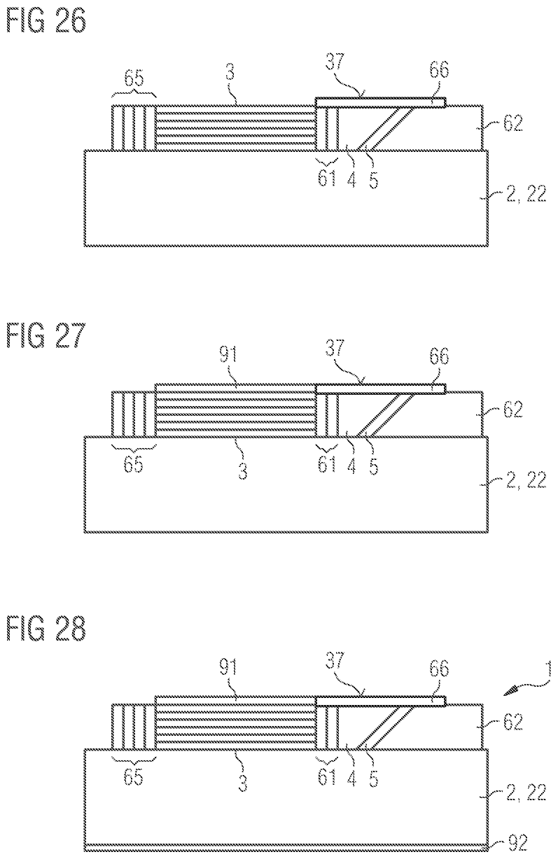

In the step of FIG. 26, the anti-reflective coating 66 is applied, resulting in the emission side 37.

Finally, FIG. 28 illustrates that the electrical contact layers 91, 92 are attached to the substitute substrate 22 as well as to the semiconductor layer sequence 3.

The process of FIGS. 17 to 28 is used as an example for manufacturing semiconductor chips 1 similar to that shown in FIG. 15, but can of course be adapted to the manufacturing requirements for semiconductor chips 1 according to the other embodiments.

Specifically, FIGS. 29 to 31 concern exemplary embodiments of semiconductor chips 1 provided with anti-beam-tilt optics 7, that is, optics that can compensate for misalignment of the outward side 45 and/or undesired tilting of the radiation R, relative to the carrier 2. Thus, HCSEL designs can be efficiently realized.

Due to tolerances in the realization of the outward side 45 in the etching process, there is a slope or skew in the radiation angle, also referred to as tilt. For example, a +/−1° variation in the outward side 45 means a tilt of +/−5° of the emitted radiation R, for example, due to refractive index differences. This is very unfavorable for many applications that require adjustment, collimation and/or focusing of the radiation R.

By incorporating appropriate lens designs, for example in the GaN substrate 21, these output beam tilts can be compensated for, analogously to a radial LED, for example. In particular, since the laser mode is typically only a few 100 nm to 2 μm wide at its starting point, but the carrier 2 is much thicker, the beam size at the 45° outward side 45 can be assumed to be a point source for the lens design. The carrier thickness also provides a good definition of the spacing of the lens surface. For example, appropriate radial lens shapes can be realized using etching techniques. Other lens shapes can also be, for example, meta-optical structures or diffractive structures. As a further advantage, compression and/or fast-axis collimation or precollimation can be performed here or integrated into the optical functionality.

A tilt correction is accordingly illustrated in FIG. 29. To simplify the illustration, the high-refractive index layer 4 and the low-refractive index coating 5 are shown only very schematically.

As is also possible in all other exemplary embodiments, the further facet 36 may also be oriented at a 45° angle to the growth direction G. The outcoupling mirror 61 may also be disposed between the carrier 2 and the region of the semiconductor layer sequence 3 with the at least one active zone 33, as is also possible in all other exemplary embodiments.

In all other respects, the comments on FIGS. 1 to 28 apply in the same way to FIG. 29, and vice versa.

According to FIG. 30, a fast axis correction is also performed in addition to the tilt correction.

In addition, as is equally possible in all other exemplary embodiments, a luminescent layer 67 may be present on or in place of the anti-reflective coating 66 for wavelength modification of the radiation R.

In all other respects, the comments on FIG. 29 apply in the same way to FIG. 30, and vice versa.

In FIG. 31 it is shown that the optics 7 can be designed as a diffractive optical element or as a meta-optics.

In all other respects, the comments on FIGS. 29 and 30 apply in the same way to FIG. 31.

FIG. 32 shows an exemplary embodiment of a component 10 comprising a semiconductor chip 1 according to one of the preceding exemplary embodiments. The semiconductor chip 1 is located on a mounting platform 11, for example, a ceramic substrate. The mounting platform 11 is provided with electrically conductive coatings 12 for electrically contacting the semiconductor chip 1. For example, the electrical contacting is performed by means of an electrical connection 15, which may be a bonding wire.

A semiconductor chip 1 is thus mounted, for example, in an SMD package, which may have contact surfaces on the underside for soldering to a printed circuit board. The package substrate, that is, the mounting platform 11, can be a ceramic, for example, made of AlN, which has electrical vias between its main sides. In addition to the two electrical contacts, a further potential-free contact for heat dissipation can be implemented on a lower side.

For mechanical protection, the semiconductor chip 1 may be encapsulated in the package, not drawn, for example, with an organic encapsulant, such as an epoxy resin, or with a silicone. If necessary, further optical elements, for example lenses, may be part of the component 10 or the package.

In all other respects, the comments on FIGS. 29 to 31 apply in the same way to FIG. 32.

The housing substrate, that is, the mounting platform 11, can also be a metal leadframe, for example, made of Cu, such as a QFN housing. For this purpose, leadframe parts 14 can be present, which are mechanically connected to each other with a carrier material 13.

In all other respects, the comments on FIG. 32 apply in the same way to FIG. 33.

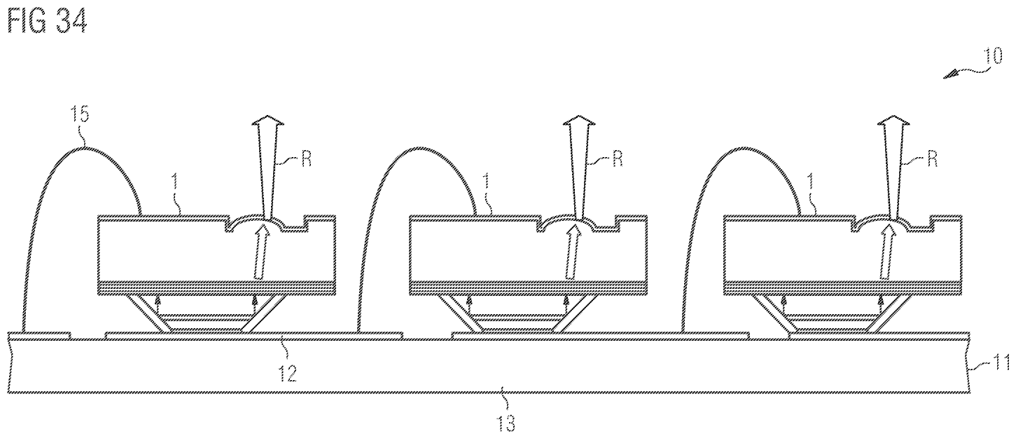

The component 10 according to FIG. 34 contains a plurality of semiconductor chips 1, whereby all the semiconductor chips 1 can be identical in construction or different types of semiconductor chips 1 can be installed, for example, for generating radiation R of different colors.

That is, a plurality of the semiconductor chips 1 are assembled and contacted on a common assembly platform 11. The electrical connection of several semiconductor chips 1 is made, for example, as a series circuit. This allows commercially available drivers to be used and reduces the required wire cross-sections. Several electrical strings per mounting platform 11 are possible.

The common mounting platform 11 may be designed as an SMD package, for example, based on at least one ceramic, as shown in FIG. 32. Alternatively, the mounting platform 11 may be designed as a printed circuit board made of a metal substrate, for example, Al or Cu, a dielectric with high thermal conductivity and the structured conductor plane.

For mechanical protection, the semiconductor chips 1 may again be encapsulated, for example, with an organic encapsulant, such as epoxy resin, or with a silicone. Further optical elements, such as lenses, can be part of the structure.

The component 10 may comprise a suitable component, such as an NTC, for temperature monitoring, not drawn.

In the case of a printed circuit board as the mounting platform 11, the carrier 13 may have solder pads or a connector for electrical contacting and drill holes for mounting on a heat sink, not shown.

By means of the optics 7, it is possible in particular to precisely match the radiation directions of the individual semiconductor chips 1 to each other. For this purpose, the optics 7 can optionally be individually adapted to the respective requirements, that is, at semiconductor chip level.

The components shown in the figures preferably follow one another in the sequence indicated, in particular directly one after the other, unless otherwise described. Components not touching each other in the figures are preferably spaced apart. Insofar as lines are drawn parallel to one another, the associated surfaces are preferably likewise aligned parallel to one another. Furthermore, the relative positions of the drawn components to each other are correctly reproduced in the figures, unless otherwise specified.

The invention described herein is not limited by the description based on the embodiments. Rather, the invention encompasses any new feature as well as any combination of features, which in particular includes any combination of features in the patent claims, even if this feature or combination itself is not explicitly stated in the patent claims or embodiments.

1. An optoelectronic semiconductor chip comprising
a carrier,
a semiconductor layer sequence on the carrier having at least one active zone for generating a radiation,
an optical high-refractive index layer on an outcoupling facet of the semiconductor layer sequence for outcoupling the radiation, and
an optical low-refractive index coating directly on an outward side of the high-refractive index layer for total reflection of the radiation,
wherein
the semiconductor layer sequence is configured to guide the radiation in the active zone perpendicularly to a growth direction of the semiconductor layer sequence, and
the high-refractive index layer is configured to
deflect the radiation at the outward side parallel to the growth direction,
the carrier is a substitute carrier and the radiation is emitted away from the carrier due to the outward side,
the carrier has a recess for the semiconductor layer sequence so that the carrier has a supporting surface facing the outcoupling facet, and the low-refractive index coating is applied to the supporting surface and the high-refractive index layer is seated on the low-refractive index coating, and
the semiconductor layer sequence, seen in plan view and in at least one region without an active zone, is fastened to the low-refractive index coating applied to the carrier by a fastening means.

2. The optoelectronic semiconductor chip according to claim 1,
which is a semiconductor laser,
wherein at a wavelength of maximum intensity of the radiation the high-refractive index layer has a refractive index of at least 0.6 higher than the low-refractive index layer.

3. The optoelectronic semiconductor chip according to claim 1,
wherein a refractive index difference between the active zone and the high-refractive index layer is at most 0.3,
wherein the high-refractive index layer is located directly at the outcoupling facet, and
the outcoupling facet is oriented transversely to the growth direction.

4. The optoelectronic semiconductor chip according to claim 1,
further comprising an outcoupling mirror directly on the outcoupling facet,
wherein the high-refractive index layer is located directly on the outcoupling mirror and the outcoupling facet is oriented parallel to the growth direction.

5. The optoelectronic semiconductor chip according to claim 1,
wherein the high-refractive index layer is a planarization layer for the outcoupling facet and/or for the outcoupling mirror.

6. The optoelectronic semiconductor chip according to claim 1,
wherein the high-refractive index layer is an angle correction layer for the outcoupling facet such that an angle between the outward side and the outcoupling facet is between 0.1° and 20°, inclusive.

7. The optoelectronic semiconductor chip according to claim 1,
further comprising a metallization reflective to the radiation and located directly on a side of the low-refractive index coating opposite the outcoupling facet.

8. The optoelectronic semiconductor chip according to claim 1,
wherein the low-refractive index coating is perforated at a contact side of the semiconductor layer sequence facing the carrier, so that an electrical contacting means is guided through the low-refractive index coating to the semiconductor layer sequence,
wherein at the supporting surface of the carrier the low-refractive index coating is located directly on the carrier.

9. The optoelectronic semiconductor chip according to claim 8,
wherein a gap is located at the contact side between the low-refractive index coating and the high-refractive index layer.

10. The optoelectronic semiconductor chip according to claim 9,
wherein in a lateral direction, that is, in direction perpendicular to the growth direction and away from the semiconductor layer sequence, a first region of the carrier adjoins the supporting surface and is oriented perpendicular to the growth direction, and a second region of the carrier adjoins the first region, and a thickness of the carrier decreases in the second region in the direction away from the semiconductor layer sequence.

11. The optoelectronic semiconductor chip according to claim 10
wherein the fastening means is based on at least one metal or is a metal alloy.

12. The optoelectronic semiconductor chip according to claim 1,
wherein a further facet opposite the outcoupling facet is oriented obliquely with respect to the growth direction, and
wherein a further supporting surface associated with the further facet is oriented parallel to the growth direction, so that the further supporting surface is configured to reflect radiation components of the radiation reaching the further supporting surface from the active zone back into the active zone.

13. The optoelectronic semiconductor chip according to claim 1,
further comprising an optics for beam correction for the radiation,
wherein the optics is located above the exterior surface as seen in plan view.

14. The optoelectronic semiconductor chip according to claim 13,
wherein the optics are produced from the carrier.

15. A component comprising
a plurality of semiconductor chips according to claim 13, and
a mounting platform,
wherein the semiconductor chips are mounted on the mounting platform and by means of the optics of the semiconductor chips radiation directions of the semiconductor chips are adapted to each other.

16. An optoelectronic semiconductor chip comprising
a carrier,
a semiconductor layer sequence on the carrier having at least one active zone for generating a radiation,
an optical high-refractive index layer on an outcoupling facet of the semiconductor layer sequence for outcoupling the radiation, and
an optical low-refractive index coating directly on an outward side of the high-refractive index layer for total reflection of the radiation,
wherein
the semiconductor layer sequence is configured to guide the radiation in the active zone perpendicularly to a growth direction of the semiconductor layer sequence, and
the high-refractive index layer is configured to deflect the radiation at the outward side parallel to the growth direction.
